(19) United States
(12) Patent Application Publication
(10) Pub. No.: US 2023/0238313 A1
(43) Pub. Date: Jul. 27, 2023

(54) PACKAGING SUBSTRATE, GRID ARRAY PACKAGE, AND PREPARATION METHOD THEREFOR

(71) Applicant: Diodes Incorporated, Plano, TX (US)

(72) Inventors: Yang Xiaorui, Shanghai (CN); Wu Wei, Shanghai (CN)

(73) Assignee: Diodes Incorporated, Plano, TX (US)

(21) Appl. No.: 18/193,598

(22) Filed: Mar. 30, 2023

Related U.S. Application Data
(63) Continuation of application No. PCT/CN2021/133043, filed on Nov. 25, 2021.

(30) Foreign Application Priority Data
Feb. 25, 2021 (CN) 202110214174.8
Feb. 25, 2021 (CN) 202120421699.4

(51) Int. Cl. H01L 23/498; H01L 21/56; H01L 23/00

(52) U.S. Cl. CPC H01L 23/49805; H01L 21/561; H01L 24/48; H01L 23/3121

(57) ABSTRACT

Disclosed are a packaging substrate, a grid array package, and a preparation method therefor. The packaging substrate comprises a plurality of packaging units, and each packaging unit is defined by a closed packaging line. The packaging substrate comprises: a base substrate having a first surface and a second surface that are opposite to each other, a plurality of solder pads provided on the first surface, and a metal layer provided on the second surface. In a given packaging unit, the metal layer comprises a plurality of lead pads, at least one lead pad extending from an inner side of the packaging unit defined by the packaging line to an outer side. The lead pad is connected to one solder pad by means of a connecting member penetrating through the base substrate, and an orthographic projection of the connecting member on the base substrate at least partially covers the packaging line.

### CROSS-REFERENCES TO RELATED APPLICATIONS

This application is a continuation of International Patent Application No. PCT/CN2021/133043, filed Nov. 25, 2021, published as WO2022/179214 on Sep. 1, 2022 and entitled “PACKAGING SUBSTRATE, GRID ARRAY PACKAGE, AND PREPARATION METHOD THEREFOR”, which claims priority to Chinese patent application No. 202110214174.8, filed on Feb. 25, 2021 and entitled “PACKAGING SUBSTRATE, GRID ARRAY PACKAGE, AND PREPARATION METHOD THEREFOR”, and priority to Chinese patent application No. 202120421699.4, filed on Feb. 25, 2021 and entitled “PACKAGING SUBSTRATE AND GRID ARRAY PACKAGE”, the disclosures of which are hereby incorporated by reference in their entirety.

### TECHNICAL FIELD

The application relates to the field of semiconductor packaging, in particular to a packaging substrate, a grid array package, and a preparation method therefor.

### BACKGROUND ART

In semiconductor packaging, a land grid array (LGA) package has a structure similar to that of a ball grid array (BGA) package, except that a solder ball is not attached to the LGA package. Compared with the BGA package, the LGA package can be mounted on a printed circuit board (PCB) by using lead free paste instead of a solder ball containing lead that is harmful to human body.

Therefore, in countries where the use of some semiconductor packaging products is restricted due to environmental considerations, the LGA package has attracted attention as an environment-friendly “green” product.

However, the current LGA package is made by lamination of multilayer materials, and usually cannot be subjected to side plating, thus limiting the use of the LGA package.

Therefore, it is necessary to provide a novel packaging substrate for an LGA package to overcome the above defect.

### SUMMARY

The embodiments of the present application provide a novel packaging substrate, so as to obtain a land grid array package capable of being subjected to side plating by means of a structure design.

An aspect of the present application provides a packaging substrate, including a plurality of packaging units, each packaging unit being defined by a closed packaging line, wherein the packaging substrate includes: a base substrate having a first surface and a second surface that are opposite to each other; a plurality of solder pads provided on the first surface of the base substrate; and a metal layer provided on the second surface of the base substrate; wherein in one packaging unit, the metal layer includes a plurality of lead pads, at least one lead pad extends from an inner side of the packaging unit defined by the packaging line to an outer side of the packaging unit, the lead pad is connected to one solder pad by means of a connecting member penetrating through the base substrate, and an orthographic projection of the connecting member on the base substrate at least partially covers the packaging line.

In some embodiments, the packaging substrate further includes a solder mask, the solder mask being provided on the first surface of the base substrate and exposing each solder pad.

In some embodiments, the metal layer further includes at least one carrier portion, the carrier portion being used for carrying at least one chip.

Another aspect of the present application provides a grid array package having a body, the grid array package including: a packaging unit obtained by cutting the packaging substrate described above, and at least one chip provided on the metal layer of the packaging unit; wherein the body of the grid array package has at least one third surface perpendicular to the first surface, and the plurality of solder pads are provided at an edge of the first surface and extend from the first surface to the third surface.

In some embodiments, the grid array package further includes a solder mask, the solder mask being provided on the first surface and exposing each solder pad.

In some embodiments, the metal layer includes at least one carrier portion, and the at least one chip is provided on the carrier portion.

In some embodiments, the chip is connected to a lead pad of the metal layer by means of a lead.

In some embodiments, the grid array package further includes a sealing material, the sealing material encapsulating the packaging unit and the at least one chip provided on the metal layer of the packaging unit, and connecting the chip and the lead pad to form the body.

Another aspect of the present application provides a preparation method for a grid array package, including steps of: providing the packaging substrate described above; mounting at least one chip on the packaging substrate; forming a lead to connect the chip and the packaging substrate, and performing packaging using a sealing material; and performing cutting along the packaging line to expose the connecting member, so as to form a grid array package.

In some embodiments, after the step of performing cutting along the packaging line, the preparation method further includes a step of plating a surface of the exposed connecting member with gold.

Another aspect of the present application provides a grid array package, that includes a base substrate having a first surface and a second surface that are opposite to each other, a plurality of solder pads provided on the first surface of the base substrate, and a metal layer provided on the second surface of the base substrate. The metal layer includes a carrier portion and a plurality of lead pads. The grid array package also includes at least one connecting member disposed at an edge of the base substrate on a third surface perpendicular to the first surface, and the connecting member connects a solder pad with a corresponding lead pad. The grid array package also includes a chip attached to the carrier portion of the metal layer and a plurality of leads connecting the chip to the lead pads.

In some embodiments of the above grid array package, the connecting member, the corresponding lead pad, and the corresponding solder pad are made of the same material.

In some embodiments, the connecting member is formed integrally with the solder pad.

In some embodiments, a solder pad provided on the first surface extends from the first surface to the third surface perpendicular to the first surface.

In some embodiments, the connecting member is subjected to a side plating process and achieves side plating on a portion of a land grid array (LGA).

Another aspect of the present application provides a method for forming a grid array package. The method includes providing a packaging unit. The packaging unit includes a base substrate having a first surface and a second surface that are opposite to each other, a base substrate having a first surface and a second surface that are opposite to each other, a plurality of solder pads provided on the first surface of the base substrate, and a metal layer provided on the second surface of the base substrate. The metal layer includes a carrier portion and a plurality of lead pads and at least one connecting member disposed at an edge of the base substrate on a third surface perpendicular to the first surface, the connecting member connecting a solder pad with a corresponding lead pad. The method also includes attaching a chip to the carrier portion of the metal layer, forming a plurality of leads connecting the chip to the lead pads, and applying a sealing material to encapsulate the packaging unit.

In some embodiments of the above method, the connecting member, the corresponding lead pad, and the corresponding solder pad are made of the same material.

In some embodiments, the connecting member is formed integrally with the solder pad.

In some embodiments, a solder pad provided on the first surface extends from the first surface to the third surface perpendicular to the first surface.

In some embodiments, the connecting member is subjected to a side plating process and achieves side plating on a portion of a land grid array (LGA).

In this application, a land grid array package capable of being subjected to side plating is obtained by means of a structure design.

### BRIEF DESCRIPTION OF THE DRAWINGS

To more clearly illustrate the features of specific embodiments, the drawings of the embodiments are briefly described below. Obviously, the drawings described below are merely some embodiments of the present application. For ordinary researchers or practitioners in the art, other similar drawings may be obtained according to these drawings without involving inventive effort.

FIG. 1A and FIG. 1B are, respectively, a top view and a bottom view of a packaging substrate according to an embodiment of the present application.

FIG. 2 is a sectional view taken along A-A′ in FIG. 1A and FIG. 1B.

FIG. 3A and FIG. 3B are, respectively, a sectional view and a perspective view of a grid array package according to an embodiment of the present application.

### DETAILED DESCRIPTION OF THE EMBODIMENTS

The present application is described below in further details with reference to specific embodiments. It is obvious that the described embodiments are merely some of the applications of the present application, rather than all of them. It should be understood that these embodiments are only used to illustrate the characteristics of the present application and are not intended to limit the scope of the present application. All other embodiments obtained by a person of ordinary skill in the art without involving inventive effort fall within the protection scope of this application.

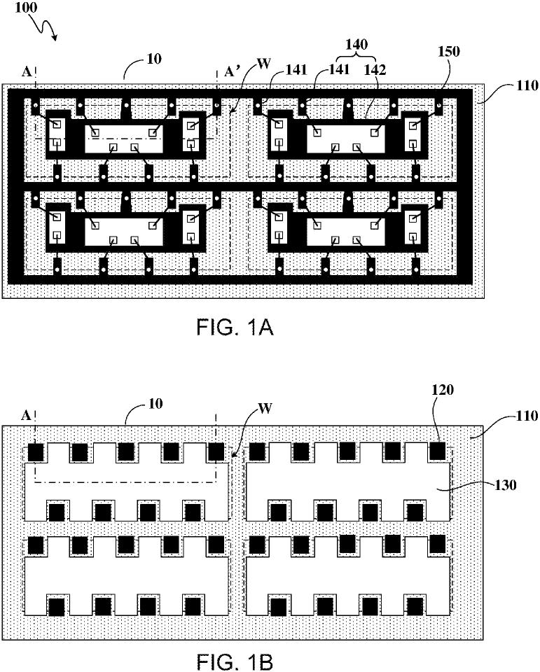

In this embodiment, referring to FIGS. 1A and 1B, a packaging substrate 100 is provided. It may be appreciated by those skilled in the art that the packaging substrate 100 includes a plurality of packaging units 10, each packaging unit 10 being defined by a closed packaging line W.

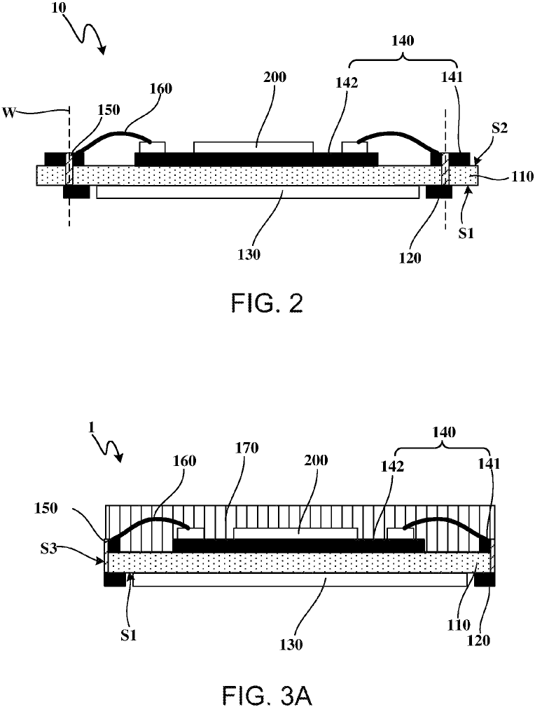

The packaging substrate 100 is described in detail below with reference to FIG. 1A, FIG. 1B, and FIG. 2.

Referring to FIG. 1A, FIG. 1B, and FIG. 2, the packaging substrate 100 includes a base substrate 110, the base substrate 110 having a first surface S1 and a second surface S2 that are opposite to each other.

Referring to FIG. 1B and FIG. 2, a plurality of solder pads 120 and a solder mask 130 are provided on the first surface S1 of the base substrate 110, the solder mask 130 exposing each solder pad 120.

Referring to FIG. 1A and FIG. 2, a metal layer 140 is provided on the second surface S2 of the base substrate 110, the metal layer 140 including a plurality of lead pads 141 and a carrier portion 142, the carrier portion 142 being used for carrying at least one chip 200. Referring to FIG. 1A and FIG. 2, the lead pad 141 extends from an inner side of the packaging unit 10 defined by the packaging line W to an outer side of the packaging unit 10, that is, the lead pad 141 has a portion on the inner side of the packaging unit 10 defined by the packaging line W and a portion on the outer side of the packaging unit 10 defined by the packaging line W. When cutting is performed subsequently along the packaging line W, the lead pad 141 is cut into two portions.

In order to achieve electrical connection between the chip 200 provided on the second surface S2 of the base substrate 110 and the solder pad 120 on the first surface S1 of the base substrate 110, referring to FIG. 2, the lead pad 141 is connected to a corresponding solder pad 120 by means of a connecting member 150 penetrating through the base substrate 110. It may be appreciated by those skilled in the art that each of the lead pads 141 corresponds to one of the solder pads 120. The connecting member 150 is particularly configured such that an orthographic projection thereof on the base substrate 110 at least partially covers the packaging line W, that is, the connecting member 150 has a portion on one side of the packaging line W and on the inner side of the packaging unit 10 defined by the packaging line W, and a portion on the other side of the packaging line W and on the outer side of the packaging unit 10 defined by the packaging line W, such that when cutting is performed subsequently along the packaging line W, the connecting member 150 is cut into two portions, and the cut surface is exposed.

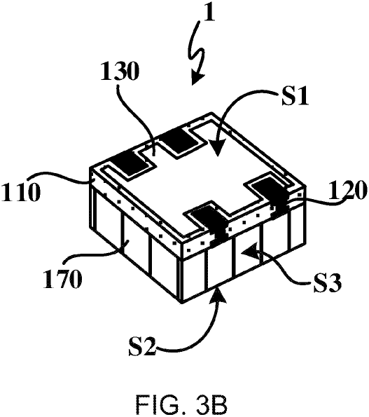

Accordingly, upon provision of a package, in particular a grid array package 1, the packaging substrate 100 as shown in FIG. 1A, FIG. 1B, and FIG. 2 may first be formed using a conventional method known in the art. After the chip 200 is mounted, a lead 160 is formed using a conventional method known in the art, so as to connect the chip 200 and the lead pad 141, as shown in FIG. 3A. Subsequently, packaging is performed using a conventional method known in the art with a sealing material 170, and finally the grid array package 1 is formed after cutting is performed along the packaging line W, as shown in FIG. 3A and FIG. 3B.

Referring to FIG. 1A and FIG. 2, since the connecting member 150 is configured such that the orthographic projection thereof on the base substrate 110 at least partially covers the packaging line W, in the package formed after the cutting, the surface of the connecting member 150 is exposed. It may be appreciated by those skilled in the art that when the connecting member 150, the lead pad 141, and the solder pad 120 are made of the same material, the connecting member 150 may be formed integrally with the solder pad 120. That is, in the grid array package 1 shown in FIG. 3B, the solder pad 120 provided on first surface S1 extends from the first surface S1 to a third surface S3 perpendicular to the first surface S1. In addition, it may be appreciated by those skilled in the art that a step of plating surfaces of the solder pad 120 and the connecting member 150 with gold may be performed, and the step of plating with gold may be implemented using a conventional method known in the art. Further, as shown in FIG. 1B, each packaging unit 10 has nine solder pads 120, five solder pads 120 in an upper row and four solder pads 120 in a lower row. It can be seen that the solder pads 120 in the upper row and the solder pads 120 in the lower row are staggered. In the example of FIG. 1B, the four solder pads 120 in the lower row are aligned to the gaps between adjacent solder pads 120 in the upper row. Of course, other staggered arrangements can also be implemented. Similarly, as shown in FIG. 1A, the lead pads 141 corresponding to the solder pads are also arranged in a staggered manner. The staggered arrangement of the solder pads and lead pads offer many advantages, compared with non-staggered arrangement. For example, in the cutting operation to separate the packaging units, the staggered arrangement can reduce the metal area contacted by the cutting knife, that is, it can reduce the cutting stress. Further, the staggered arrangement can also prevent interference in the soldering or welding process. Staggered pads can also increase the shear area of the circuit board, improve welding strength and reliability, and improve the density of the circuit board. Further, each packaging unit 10 has its own connecting members 150 and solder pads 120. The connecting members and solder pads are not shared with other packaging units.

Therefore, the final grid array package 1 obtained in the present application has a solder pad on the side face thereof, in addition to the solder pad conventionally provided on the bottom surface, thereby overcoming the drawback that the LGA is incapable of being subjected to a side plating process, and achieving side plating on a portion of the LGA.

The present application has been described using the related embodiments described above. However, the above-mentioned embodiments are merely examples of the present application. It should be noted that the disclosed embodiments do not limit the scope of the present application. On the contrary, all modifications and equivalent arrangements that come within the spirit and range of the claims shall fall within the scope of the present application.

What is claimed is:

1. A packaging substrate comprising a plurality of packaging units, each packaging unit being defined by a closed packaging line, and characterized in that the packaging substrate comprises:
a base substrate having a first surface and a second surface that are opposite to each other;
a plurality of solder pads provided on the first surface of the base substrate; and
a metal layer provided on the second surface of the base substrate;
wherein in one packaging unit, the metal layer comprises a plurality of lead pads, at least one lead pad extends from an inner side of the packaging unit defined by the packaging line to an outer side of the packaging unit, the lead pad is connected to one solder pad by means of a connecting member penetrating through the base substrate, and an orthographic projection of the connecting member on the base substrate at least partially covers the packaging line.

2. The packaging substrate according to claim 1, wherein the packaging substrate further comprises a solder mask, the solder mask being provided on the first surface of the base substrate and exposing each solder pad.

3. The packaging substrate according to claim 1, wherein the metal layer further comprises at least one carrier portion, the carrier portion being used for carrying at least one chip.

4. A grid array package having a body, and characterized in that the grid array package comprises:
a packaging unit obtained by cutting the packaging substrate of claim 1, and at least one chip provided on the metal layer of the packaging unit;
wherein the body of the grid array package has at least one third surface perpendicular to the first surface, and the plurality of solder pads are provided at an edge of the first surface and extend from the first surface to the third surface.

5. The grid array package according to claim 4, wherein the grid array package further comprises a solder mask, the solder mask being provided on the first surface and exposing each solder pad.

6. The grid array package according to claim 4, wherein the metal layer comprises at least one carrier portion, and the at least one chip is provided on the carrier portion.

7. The grid array package according to claim 4, wherein the chip is connected to a lead pad of the metal layer by means of a lead.

8. The grid array package according to claim 7, wherein the grid array package further comprises a sealing material, the sealing material encapsulating the packaging unit and the at least one chip provided on the metal layer of the packaging unit, and connecting the chip and the lead pad to form the body.

9. A preparation method for a grid array package, characterized in that the preparation method comprises steps of:
providing the packaging substrate of claim 1;
mounting at least one chip on the packaging substrate;
forming a lead to connect the chip and the packaging substrate, and performing packaging using a sealing material; and
performing cutting along the packaging line to expose the connecting member, so as to form a grid array package.

10. The preparation method according to claim 9, wherein after the step of performing cutting along the packaging line, the preparation method further comprises a step of plating a surface of the exposed connecting member with gold.

11. A grid array package, comprising:
a base substrate having a first surface and a second surface that are opposite to each other;
a plurality of solder pads provided on the first surface of the base substrate;
a metal layer provided on the second surface of the base substrate; the metal layer including a carrier portion and a plurality of lead pads;
at least one connecting member disposed at an edge of the base substrate on a third surface perpendicular to the first surface, the connecting member connecting a solder pad with a corresponding lead pad;
a chip attached to the carrier portion of the metal layer; and
a plurality of leads connecting the chip to the lead pads.

12. The grid array package of claim 11, wherein the connecting member, the corresponding lead pad, and the corresponding solder pad are made of the same material.

13. The grid array package of claim 11, wherein the connecting member is formed integrally with the solder pad.

14. The grid array package of claim 11, wherein a solder pad provided on the first surface extends from the first surface to the third surface perpendicular to the first surface.

15. The grid array package of claim 11, wherein the connecting member is subjected to a side plating process and achieves side plating on a portion of a land grid array (LGA).

16. A method for forming a grid array package, the method comprising:
providing a packaging unit, comprising:
a base substrate having a first surface and a second surface that are opposite to each other;
a plurality of solder pads provided on the first surface of the base substrate;
a metal layer provided on the second surface of the base substrate; the metal layer including a carrier portion and a plurality of lead pads; and
at least one connecting member disposed at an edge of the base substrate on a third surface perpendicular to the first surface, the connecting member connecting a solder pad with a corresponding lead pad;
attaching a chip to the carrier portion of the metal layer;
forming a plurality of leads connecting the chip to the lead pads; and
applying a sealing material to encapsulate the packaging unit.

17. The method of claim 16, wherein the connecting member, the corresponding lead pad, and the corresponding solder pad are made of the same material.

18. The method of claim 16, wherein the connecting member is formed integrally with the solder pad.

19. The method of claim 16, wherein a solder pad provided on the first surface extends from the first surface to the third surface perpendicular to the first surface.

20. The method of claim 16, wherein the connecting member is subjected to a side plating process and achieves side plating on a portion of a land grid array (LGA).
